(19) United States
(12) Patent Application Publication
(10) Pub. No.: US 2024/0268038 A1
(43) Pub. Date: Aug. 8, 2024

(54) PRINTED WIRING BOARD

(71) Applicant: IBIDEN CO., LTD., Ogaki (JP)

(72) Inventors: Susumu KAGOHASHI, Ogaki (JP); Jun SAKAI, Ogaki (JP); Kyohei YOSHIKAWA, Ogaki (JP)

(73) Assignee: IBIDEN CO., LTD., Ogaki (JP)

(21) Appl. No.: 18/434,888

(22) Filed: Feb. 7, 2024

(30) Foreign Application Priority Data
Feb. 8, 2023 (JP) 2023-017245

(51) Int. Cl. H05K 3/46; H05K 1/03; H05K 1/09; H05K 3/40; H05K 3/42

(52) U.S. Cl. CPC H05K 3/4688; H05K 1/0306; H05K 1/0353; H05K 1/09; H05K 3/4038; H05K 3/423; H05K 2201/0209; H05K 2201/0212; H05K 2201/0323; H05K 2201/0326

(57) ABSTRACT

A printed wiring board includes a first conductor layer, a resin insulating layer including glass particles and resin, a second conductor layer formed on a surface of the resin insulating layer and including a seed layer and an electrolytic plating layer, and a via conductor connecting the first conductor layer and second conductor layer and including the seed layer and electrolytic plating layer extending from the second conductor layer. The second conductor layer and the via conductor are formed such that the second conductor layer includes signal wirings and that the seed layer is formed by sputtering an alloy including copper, aluminum, and one or more metals selected from nickel, zinc, gallium, silicon, and magnesium, and the resin insulating layer is formed such that the surface of the resin insulating layer includes the resin and that an inner wall surface in the opening includes the resin and the glass particles.

### CROSS-REFERENCE TO RELATED APPLICATIONS

The present application is based upon and claims the benefit of priority to Japanese Patent Application No. 2023-017245, filed Feb. 8, 2023, the entire contents of which are incorporated herein by reference.

### BACKGROUND OF THE INVENTION

### Field of the Invention

A technology disclosed herein relates to a printed wiring board.

### Description of Background Art

Japanese Patent Application Laid-Open Publication No. 2000-124602 describes a printed wiring board having a resin substrate, a resin insulating layer formed on the resin substrate, and a conductor circuit. The entire contents of this publication are incorporated herein by reference.

### SUMMARY OF THE INVENTION

According to one aspect of the present invention, a printed wiring board includes a first conductor layer, a resin insulating layer formed on the first conductor layer and including glass particles and resin, a second conductor layer formed on a surface of the resin insulating layer and including a seed layer and an electrolytic plating layer formed on the seed layer, and a via conductor formed in an opening formed in the resin insulating layer such that the via conductor is connecting the first conductor layer and the second conductor layer and includes the seed layer and electrolytic plating layer extending from the second conductor layer. The second conductor layer and the via conductor are formed such that the second conductor layer includes signal wirings and that the seed layer is formed by sputtering an alloy including copper, aluminum, and one or more metals selected from nickel, zinc, gallium, silicon, and magnesium, and the resin insulating layer is formed such that the surface of the resin insulating layer includes the resin and that an inner wall surface in the opening includes the resin and the glass particles.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional view schematically illustrating a printed wiring board according to an embodiment of the present invention;

FIG. 2A is a cross-sectional view schematically illustrating a method for manufacturing a printed wiring board according to an embodiment of the present invention;

FIG. 2B is a cross-sectional view schematically illustrating a method for manufacturing a printed wiring board according to an embodiment of the present invention;

FIG. 2C is a cross-sectional view schematically illustrating a method for manufacturing a printed wiring board according to an embodiment of the present invention;

FIG. 2D is a cross-sectional view schematically illustrating a method for manufacturing a printed wiring board according to an embodiment of the present invention;

FIG. 2E is a cross-sectional view schematically illustrating a method for manufacturing a printed wiring board according to an embodiment of the present invention;

FIG. 2F is a cross-sectional view schematically illustrating a method for manufacturing a printed wiring board according to an embodiment of the present invention; and

FIG. 2G is a cross-sectional view schematically illustrating a method for manufacturing a printed wiring board according to an embodiment of the present invention.

### DETAILED DESCRIPTION OF THE EMBODIMENTS

Embodiments will now be described with reference to the accompanying drawings, wherein like reference numerals designate corresponding or identical elements throughout the various drawings.

### Embodiment

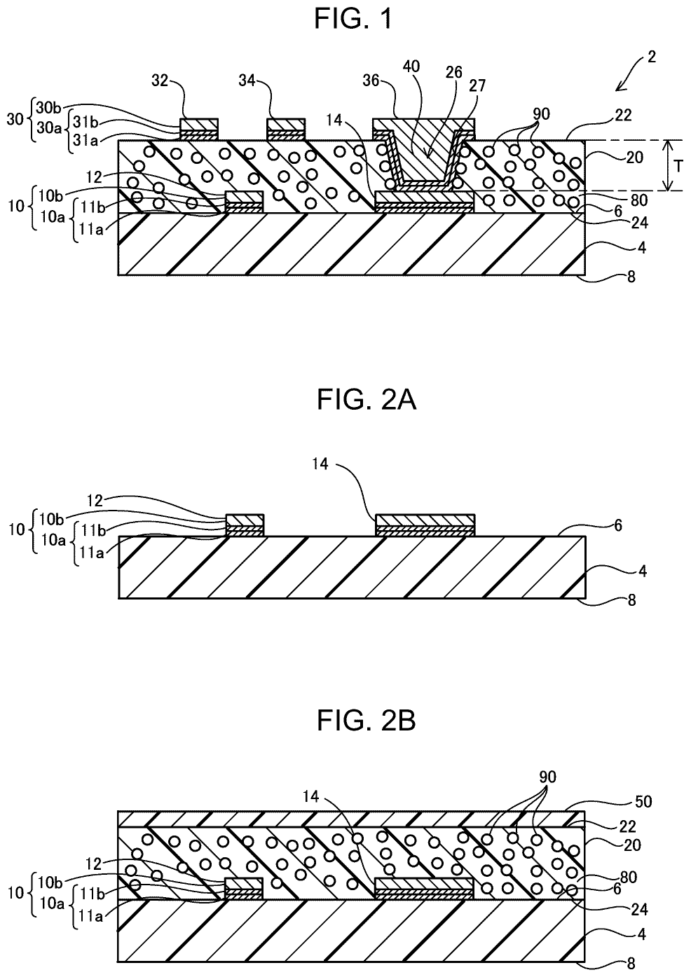

FIG. 1 is a cross-sectional view illustrating a printed wiring board 2 of an embodiment. As illustrated in FIG. 1, the printed wiring board 2 includes an insulating layer 4, a first conductor layer 10, a resin insulating layer 20, a second conductor layer 30, and a via conductor 40.

The insulating layer 4 is formed using a resin. The insulating layer 4 may contain inorganic particles such as glass particles. The insulating layer 4 may contain a reinforcing material such as a glass cloth. The insulating layer 4 has a third surface 6 and a fourth surface 8 on the opposite side with respect to the third surface 6.

The first conductor layer 10 is formed on the third surface 6 of the insulating layer 4. The first conductor layer 10 includes a signal wiring 12 and a pad 14. Although not illustrated in the drawing, the first conductor layer 10 also includes conductor circuits other than the signal wiring 12 and the pad 14. The first conductor layer 10 is mainly formed of copper. The first conductor layer 10 is formed of a seed layer (10a) and an electrolytic plating layer (10b) on the seed layer (10a). The seed layer (10a) is formed by sputtering. The seed layer (10a) is formed of a first layer (11a) on the third surface 6 and a second layer (11b) on the first layer (11a). The first layer (11a) is in contact with the insulating layer 4. The second layer (11b) is not essential.

The first layer (11a) is formed of an alloy containing copper, aluminum, and a specific metal. Examples of specific metals include nickel, zinc, gallium, silicon, and magnesium. The alloy preferably contains one type of specific metal, or two types of specific metals, or three types of specific metals. The aluminum content in the alloy is 1.0 at % or more and 15.0 at % or less. An example of a specific metal is silicon. The content of the specific metal in the alloy is 0.5 at % or more and 10.0 at % or less. The first layer (11a) may contain impurities. Examples of the impurities are oxygen and carbon. The first layer (11a) can contain oxygen or carbon. The first layer (11a) can contain oxygen and carbon. In the embodiment, the alloy further contains carbon. The carbon content in the alloy is 50 ppm or less. The alloy further contains oxygen. The oxygen content in the alloy is 100 ppm or less. The values of the contents of the elements described above are examples. Among the elements that form the first layer (11a), the copper content is the largest. The aluminum content is the next largest. The content of the specific metal is less than the aluminum content. Therefore, copper is a primary metal, aluminum is a first secondary metal, and the specific metal is a second secondary metal. The content of the impurities is smaller than the content of the specific metal.

The second layer (11b) is formed of copper. A content of copper forming the second layer (11b) is 99.9 at % or more. The copper content in the second layer (11b) is preferably 99.95 at % or more. The electrolytic plating layer (10b) is formed of copper. A content of copper forming the electrolytic plating layer (10b) is 99.9 at % or more. The copper content in the electrolytic plating layer (10b) is preferably 99.95 at % or more.

The resin insulating layer 20 is formed on the third surface 6 of the insulating layer 4 and on the first conductor layer 10. The resin insulating layer 20 has a first surface 22 and a second surface 24 on the opposite side with respect to the first surface 22. An opening 26 exposing the pad 14 is formed in the resin insulating layer 20. The resin insulating layer 20 is formed of a resin 80 and a large number of inorganic particles 90 dispersed in the resin 80. The resin 80 is an epoxy resin. Examples of the resin include a thermosetting resin and a photocurable resin. The inorganic particles 90 are glass particles. The inorganic particles 90 may be alumina particles.

The first surface 22 of the resin insulating layer 20 is formed only of the resin 80. No inorganic particles 90 are exposed from the first surface 22. The first surface 22 does not include surfaces of inorganic particles 90. No unevenness is formed on the first surface 22 of the resin insulating layer 20. The first surface 22 is not roughened. The first surface 22 is formed smooth. On the other hand, the inorganic particles 90 are exposed on an inner wall surface 27 of the opening 26. The inner wall surface 27 of the opening 26 includes surfaces of the inorganic particles 90. The inner wall surface 27 of the opening 26 has unevenness. The inner wall surface 27 of the opening 26 is formed of an exposed surface of the resin 80 and exposed surfaces of the inorganic particles 90.

A thickness (T) of the resin insulating layer 20 is two or more times a thickness of the second conductor layer 30. The thickness (T) of the resin insulating layer 20 is a distance between the first surface 22 and the upper surface of the first conductor layer 10.

The second conductor layer 30 is formed on the first surface 22 of the resin insulating layer 20. The second conductor layer 30 includes a first signal wiring 32, a second signal wiring 34, and a land 36. Although not illustrated in the drawing, the second conductor layer 30 also includes conductor circuits other than the first signal wiring 32, the second signal wiring 34, and the land 36. The first signal wiring 32 and the second signal wiring 34 form a pair wiring. The second conductor layer 30 is mainly formed of copper. The second conductor layer 30 is formed of a seed layer (30a) and an electrolytic plating layer (30b) on the seed layer (30a). The seed layer (30a) is formed by sputtering. The seed layer (30a) is formed of a first layer (31a) on the first surface 22 and a second layer (31b) on the first layer (31a). The first layer (31a) is in contact with the first surface 22. The second layer (31b) is not essential.

The first layer (31a) that forms the second conductor layer 30 is similar to the first layer (11a) that forms the first conductor layer 10.

The second layer (31b) that forms the second conductor layer 30 is similar to the second layer (11b) that forms the first conductor layer 10. The electrolytic plating layer (30b) is formed of copper.

The via conductor 40 is formed in the opening 26. The via conductor 40 connects the first conductor layer 10 and the second conductor layer 30. In FIG. 1, the via conductor 40 connects the pad 14 and the land 36. The via conductor 40 is formed of a seed layer (30a) and an electrolytic plating layer (30b) on the seed layer (30a). The seed layer (30a) that forms the via conductor 40 and the seed layer (30a) that forms the second conductor layer 30 are common. The seed layer (30a) that forms the via conductor 40 is formed of a first layer (31a), which is formed on the inner wall surface 27 of the opening 26 and on the pad 14 exposed from the opening 26, and a second layer (31b) on the first layer (31a). The first layer (31a) is in contact with the upper surface of the pad 14 and the inner wall surface 27.

### Method for Manufacturing Printed Wiring Board

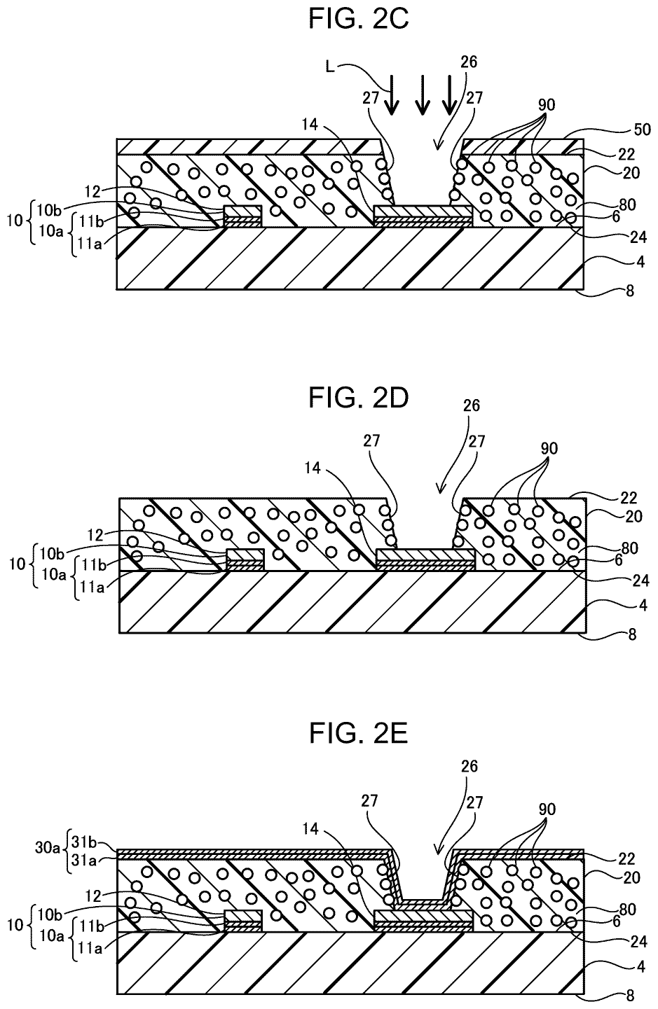

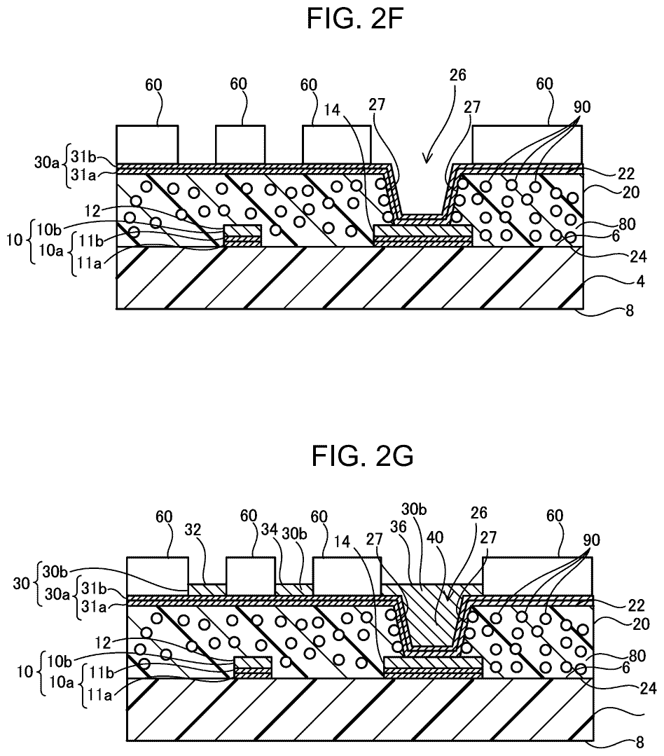

FIGS. 2A-2G illustrate a method for manufacturing the printed wiring board 2 of the embodiment. FIGS. 2A-2G are cross-sectional views. FIG. 2A illustrates the insulating layer 4 and the first conductor layer 10 formed on the third surface 6 of the insulating layer 4. The first conductor layer 10 is formed using a semi-additive method. The first layer (11a) and the second layer (11b) are formed by sputtering. The first layer (11a) is formed of an alloy containing copper, aluminum, and a specific metal. An example of a specific metal is silicon or nickel. The second layer (11b) is formed of copper. The electrolytic plating layer (10b) is formed by electrolytic plating. The electrolytic plating layer (10b) is formed of copper.

As illustrated in FIG. 2B, the resin insulating layer 20 and a protective film 50 are formed on the insulating layer 4 and the first conductor layer 10. The second surface 24 of the resin insulating layer 20 faces the third surface 6 of the insulating layer 4. The protective film 50 is formed on the first surface 22 of the resin insulating layer 20. The first surface 22 of the resin insulating layer 20 is formed only of the resin 80. No inorganic particles 90 are exposed from the first surface 22. The first surface 22 does not include surfaces of inorganic particles 90. No unevenness is formed on the first surface 22 of the resin insulating layer 20.

The protective film 50 completely covers the first surface 22 of the resin insulating layer 20. An example of the protective film 50 is a film formed of polyethylene terephthalate (PET). A release agent is formed between the protective film 50 and the resin insulating layer 20.

As illustrated in FIG. 2C, laser (L) is irradiated from above the protective film 50. The laser (L) penetrates the protective film 50 and the resin insulating layer 20 at the same time. The opening 26 for a via conductor reaching the pad 14 of the first conductor layer 10 is formed. The laser (L) is, for example, UV laser, or CO₂ laser. The pad 14 is exposed from the opening 26. When the opening 26 is formed, the first surface 22 is covered by the protective film 50. Therefore, when the opening 26 is formed, even when the resin scatters, adherence of the resin to the first surface 22 is suppressed.

After that, the inside of the opening 26 is cleaned. By cleaning the inside of the opening 26, resin residues generated when the opening 26 is formed are removed. The cleaning of the inside of the opening 26 is performed using plasma. That is, the cleaning is performed with a dry process. The cleaning includes a desmear treatment. By the plasma, the resin 80 is selectively removed. The plasma removes the resin 80 faster than the inorganic particles 90. The inner wall surface 27 of the opening 26 is roughened with plasma.

By cleaning the inside of the opening 26, the inorganic particles 90 are exposed on the inner wall surface 27 of the opening 26 (FIG. 2C). The inner wall surface 27 of the opening 26 includes surfaces of the inorganic particles 90. Unevenness is formed on the inner wall surface 27 of the opening 26. On the other hand, the first surface 22 of the resin insulating layer 20 is covered by the protective film 50. The first surface 22 is not affected by the plasma. The first surface 22 is formed of the resin 80 only. No inorganic particles 90 are exposed from the first surface 22. The first surface 22 does not include surfaces of inorganic particles 90. No unevenness is formed on the first surface 22 of the resin insulating layer 20. The first surface 22 is formed smooth.

As illustrated in FIG. 2D, the protective film 50 is removed from the resin insulating layer 20. After the protective film 50 is removed, no roughening of the first surface 22 of the resin insulating layer 20 is performed.

As illustrated in FIG. 2E, the seed layer (30a) is formed on the first surface 22 of the resin insulating layer 20. The seed layer (30a) is formed by sputtering. The formation of the seed layer (30a) is performed in a dry process. The seed layer (30a) is also formed on the upper surface of the pad 14 exposed from the opening 26 and on the inner wall surface 27 of the opening 26. The first layer (31a) is formed on the first surface 22 by sputtering. The first layer (31a) is formed on the inner wall surface 27 and the pad 14, which are exposed from the opening 26, by sputtering. The second layer (31b) is formed on the first layer (31a) by sputtering.

The first layer (31a) of the seed layer (30a) is formed of an alloy containing copper, aluminum and silicon. Aluminum has high ductility and high malleability. Therefore, adhesion between resin insulating layer 20 and the first layer (31a) is high. It is thought that, even when the resin insulating layer 20 expands or contracts, the seed layer (30a) containing aluminum can follow the expansion or contraction. Even when the first surface 22 is smooth, the seed layer (30a) is unlikely to peel off from the resin insulating layer 20. It is thought that aluminum is easily oxidized. It is thought that the first layer (31a) formed on the inner wall surface 27 of the opening 26 adheres to the inorganic particles 90 via the oxygen in the inorganic particles 90 (glass particles) forming the inner wall surface 27. The first layer (31a) and the inner wall surface 27 are strongly bonded to each other. Adhesion between the inner wall surface 27 of the opening 26 and the first layer (31a) can be increased. The seed layer (30a) is unlikely to peel off from the inner wall surface 27.

As illustrated in FIG. 2F, a plating resist 60 is formed on the seed layer (30a). The plating resist 60 has openings for forming the first signal wiring 32, the second signal wiring 34, and the land 36 (FIG. 1).

As illustrated in FIG. 2G, the electrolytic plating layer (30b) is formed on the seed layer (30a) exposed from the plating resist 60. The electrolytic plating layer (30b) fills the opening 26. The first signal wiring 32, the second signal wiring 34, and the land 36 are formed by the seed layer (30a) and the electrolytic plating film (30b) on the first surface 22. The second conductor layer 30 is formed. The via conductor 40 is formed by the seed layer (30a) and the electrolytic plating film (30b) in the opening 26. The via conductor 40 connects the pad 14 and the land 36. The first signal wiring 32 and the second signal wiring 34 form a pair wiring.

After that, the plating resist 60 is removed. The seed layer (30a) exposed from the electrolytic plating layer (30b) is removed. The second conductor layer 30 and the via conductor 40 are formed at the same time. The printed wiring board 2 (FIG. 1) of the embodiment is obtained.

In the printed wiring board 2 (FIG. 1) of the embodiment, the first surface 22 of the resin insulating layer 20 is formed of the resin 80. The inorganic particles 90 are not exposed on the first surface 22. No unevenness is formed on the first surface 22. An increase in standard deviation of a relative permittivity in a portion near the first surface 22 of the resin insulating layer 20 is suppressed. The relative permittivity of the first surface 22 does not significantly vary depending on a location. Even when the first signal wiring 32 and the second signal wiring 34 are in contact with the first surface 22, a difference in propagation speed of an electric signal between the first signal wiring 32 and the second signal wiring 34 can be reduced. Therefore, in the printed wiring board 2 of the embodiment, noise is suppressed. Even when a logic IC is mounted on the printed wiring board 2 of the embodiment, data transmitted via the first signal wiring 32 and data transmitted via the second signal wiring 34 arrive at the logic IC substantially without delay. Malfunction of a logic IC can be suppressed. Even when a length of the first signal wiring 32 and a length of the second signal wiring 34 are 5 mm or more, a difference in propagation speed between the two can be reduced. Even when the length of the first signal wiring 32 and the length of the second signal wiring 34 are 10 mm or more and 20 mm or less, malfunction of the logic IC can be suppressed. Although not illustrated in the drawings, each side of the printed wiring board 2 has a length of 50 mm or more. The length of each side is preferably 100 mm or more. The length of each side is 250 mm or less. A high quality printed wiring board 2 is provided.

In the printed wiring board 2 (FIG. 1) of the embodiment, the thickness (T) of the resin insulating layer 20 is two or more times the thickness of the second conductor layer 30. It is thought that, when the printed wiring board 2 is subjected to heat cycles, a stress applied between the inner wall surface 27 of the opening 26 and the via conductor 40 is greater than a stress applied between the first surface 22 and the second conductor layer 30. The inner wall surface 27 of the opening 26 has unevenness. Therefore, adhesion strength between the inner wall surface 27 of the opening 26 and the via conductor 40 is higher than adhesion strength between the first surface 22 and the second conductor layer 30. The via conductor 40 is unlikely to peel off from the resin insulating layer 20. The second conductor layer 30 is unlikely to peel off from the resin insulating layer 20.

In the printed wiring board 2 of the embodiment, the seed layer (30a) is formed by sputtering (FIG. 2E). Particles forming the seed layer (30a) perpendicularly collide with the first surface 22. Therefore, adhesion strength between the first surface 22 and the seed layer (30a) is high. On the other hand, particles forming the seed layer (30a) obliquely collide with the inner wall surface 27 of the opening 26. The inner wall surface 27 of the opening 26 has unevenness. The inner wall surface 27 of the opening 26 includes the exposed surfaces of the glass particles. The seed layer (30a) contains aluminum. Therefore, adhesion strength between the seed layer (30a) and the inner wall surface 27 of the opening 26 can be increased. A difference between the adhesion strength between the second conductor layer 30 and the first surface 22 and the adhesion strength between the via conductor 40 and the inner wall surface 27 of the opening 26 can be reduced. A stress is unlikely to concentrate on an interface between the second conductor layer 30 and the first surface 22. A stress is unlikely to concentrate on an interface between the via conductor 40 and the inner wall surface 27 of the opening 26. Even when the printed wiring board 2 is subjected to a thermal shock, the via conductor 40 is unlikely to peel off from the resin insulating layer 20. The second conductor layer 30 is unlikely to peel off from the resin insulating layer 20. A high quality printed wiring board 2 is provided.

### First Alternative Example

In a first alternative example of the embodiment, the specific metal contained in the alloy forming the first layers (11a, 31a) of the seed layers (10a, 30a) is at least one of nickel, zinc, gallium, silicon, and magnesium.

### Second Alternative Example

In a second alternative example of the embodiment, the alloy forming the first layers (11a, 31a) of the seed layers (10a, 30a) does not contain carbon.

### Third Alternative Example

In a third alternative example of the embodiment, the alloy forming the first layers (11a, 31a) of the seed layers (10a, 30a) does not contain oxygen.

Japanese Patent Application Laid-Open Publication No. 2000-124602 describes a printed wiring board having a resin substrate, a resin insulating layer formed on the resin substrate, and a conductor circuit. The conductor circuit is formed on the resin insulating layer via an alloy layer containing a specific metal. For example, the specific metal is shown in paragraph 8 of Japanese Patent Application Laid-Open Publication No. 2000-124602.

In the printed wiring board having the alloy layer of Japanese Patent Application Laid-Open Publication No. 2000-124602, it is thought that adhesion between the conductor circuit and the resin insulating layer is insufficient.

A printed wiring board according to an embodiment of the present invention includes a first conductor layer, a resin insulating layer that is formed on the first conductor layer and has an opening for a via conductor exposing the first conductor layer, a first surface, and a second surface on the opposite side with respect to the first surface, a second conductor layer that is formed on the first surface of the resin insulating layer, and a via conductor that is formed in the opening and connects the first conductor layer and the second conductor layer. The second conductor layer and the via conductor are formed of a seed layer and an electrolytic plating layer formed on the seed layer. The seed layer is formed by sputtering and is formed of an alloy containing copper, aluminum, and a specific metal, and the specific metal is at least one of nickel, zinc, gallium, silicon, and magnesium. The resin insulating layer is formed of glass particles and a resin. The second conductor layer includes signal wirings. The first surface of the resin insulating layer is formed of the resin. An inner wall surface of the opening is formed of the resin and surfaces of the glass particles.

In a printed wiring board according to an embodiment of the present invention, the seed layer is formed of an alloy containing copper, aluminum, and a specific metal. Aluminum has high ductility and high malleability. Therefore, adhesion between resin insulating layer and the seed layer is high. It is thought that aluminum is easily oxidized. It is thought that the seed layer formed on the inner wall surface of the opening adheres to the glass particles via oxygen in the glass particles forming the inner wall surface. It is thought that adhesion between the inner wall surface of the opening and the seed layer is high. Further, in a printed wiring board according to an embodiment of the present invention, the first surface of the resin insulating layer is formed of a resin. The first surface of the resin insulating layer is formed only of the resin. The first surface does not include surfaces of the inorganic particles. An increase in standard deviation of the relative permittivity in a portion near the first surface of the resin insulating layer is suppressed. The relative permittivity of the first surface of the resin insulating layer is substantially uniform. When the second conductor layer is formed on the first surface, a difference in propagation speed of an electrical signal between signal wirings included in the second conductor layer can be reduced. In the printed wiring board of the embodiment, noise is suppressed. A high quality printed wiring board is provided.

Obviously, numerous modifications and variations of the present invention are possible in light of the above teachings. It is therefore to be understood that within the scope of the appended claims, the invention may be practiced otherwise than as specifically described herein.

1. A printed wiring board, comprising:
a first conductor layer;
a resin insulating layer formed on the first conductor layer and comprising glass particles and resin;
a second conductor layer formed on a surface of the resin insulating layer and comprising a seed layer and an electrolytic plating layer formed on the seed layer; and
a via conductor formed in an opening formed in the resin insulating layer such that the via conductor is connecting the first conductor layer and the second conductor layer and includes the seed layer and electrolytic plating layer extending from the second conductor layer,
wherein the second conductor layer and the via conductor are formed such that the second conductor layer includes a plurality of signal wirings and that the seed layer is formed by sputtering an alloy comprising copper, aluminum, and at least one metal selected from the group consisting of nickel, zinc, gallium, silicon, and magnesium, and the resin insulating layer is formed such that the surface of the resin insulating layer includes the resin and that an inner wall surface in the opening includes the resin and the glass particles.

2. The printed wiring board according to claim 1, wherein the second conductor layer is formed such that the plurality of signal wirings includes a pair wiring comprising a first signal wiring and a second signal wiring.

3. The printed wiring board according to claim 1, wherein the resin insulating layer is formed such that the surface on which the second conductor layer is formed does not include the glass particles.

4. The printed wiring board according to claim 3, wherein the resin insulating layer is formed such that the surface on which the second conductor layer is formed is formed only of the resin.

5. The printed wiring board according to claim 1, wherein the resin insulating layer is formed such that the glass particles are not exposed from the surface on which the second conductor layer is formed.

6. The printed wiring board according to claim 1, wherein the second conductor layer is formed such that the at least one metal includes silicon and that a silicon content in the alloy is in the range of 0.5 at % to 10.0 at %.

7. The printed wiring board according to claim 1, wherein the second conductor layer is formed such that an aluminum content in the alloy is in a range of 1.0 at % to 15.0 at %.

8. The printed wiring board according to claim 1, wherein the second conductor layer is formed such that the alloy includes carbon and that a carbon content in the alloy is 50 ppm or less.

9. The printed wiring board according to claim 1, wherein the second conductor layer is formed such that the alloy includes oxygen and that an oxygen content in the alloy is 100 ppm or less.

10. The printed wiring board according to claim 2, wherein the resin insulating layer is formed such that the surface on which the second conductor layer is formed does not include the glass particles.

11. The printed wiring board according to claim 10, wherein the resin insulating layer is formed such that the surface on which the second conductor layer is formed is formed only of the resin.

12. The printed wiring board according to claim 2, wherein the resin insulating layer is formed such that the glass particles are not exposed from the surface on which the second conductor layer is formed.

13. The printed wiring board according to claim 2, wherein the second conductor layer is formed such that the at least one metal includes silicon and that a silicon content in the alloy is in the range of 0.5 at % to 10.0 at %.

14. The printed wiring board according to claim 2, wherein the second conductor layer is formed such that an aluminum content in the alloy is in a range of 1.0 at % to 15.0 at %.

15. The printed wiring board according to claim 2, wherein the second conductor layer is formed such that the alloy includes carbon and that a carbon content in the alloy is 50 ppm or less.

16. The printed wiring board according to claim 2, wherein the second conductor layer is formed such that the alloy includes oxygen and that an oxygen content in the alloy is 100 ppm or less.

17. The printed wiring board according to claim 3, wherein the second conductor layer is formed such that the at least one metal includes silicon and that a silicon content in the alloy is in the range of 0.5 at % to 10.0 at %.

18. The printed wiring board according to claim 3, wherein the second conductor layer is formed such that an aluminum content in the alloy is in a range of 1.0 at % to 15.0 at %.

19. The printed wiring board according to claim 3, wherein the second conductor layer is formed such that the alloy includes carbon and that a carbon content in the alloy is 50 ppm or less.

20. The printed wiring board according to claim 3, wherein the second conductor layer is formed such that the alloy includes oxygen and that an oxygen content in the alloy is 100 ppm or less.
